(19) United States
(12) Patent Application Publication
(10) Pub. No.: US 2015/0311096 A1
(43) Pub. Date: Oct. 29, 2015

(54) METHOD OF MANUFACTURING SEMICONDUCTOR DEVICE AND CLEANING PROCESSING SYSTEM

(71) Applicant: CANON KABUSHIKI KAISHA, Tokyo (JP)

(72) Inventor: Satoshi Ogawa, Yokohama-shi (JP)

(21) Appl. No.: 14/687,016

(22) Filed: Apr. 15, 2015

(30) Foreign Application Priority Data
Apr. 25, 2014 (JP) 2014-092000

(51) Int. Cl. H01L 21/67; H01L 21/02

(52) U.S. Cl. CPC H01L 21/67051; H01L 21/02076

(57) ABSTRACT

A method of manufacturing a semiconductor device by performing a plurality of substrate cleaning steps including a process for supplying a chemical solution on a substrate transported into a cleaning apparatus, a process for rotating the substrate, and a process for unloading the substrate from the cleaning apparatus is provided. In the plurality of cleaning steps, a dropping start position of the chemical solution on the substrate is set in a region on the substrate where the semiconductor device has been formed, and the dropping start position is changed at least once.

### BACKGROUND OF THE INVENTION

1. Field of the Invention

The present invention relates to a method of manufacturing a semiconductor device and a cleaning processing system.

2. Description of the Related Art

Semiconductor devices are manufactured by forming elements on the flat surface of a wafer by repeating steps such as cleaning, resist coating, dry etching, and forming a film for a substrate such as a silicon wafer. These steps include many steps of removing foreign particles (foreign substances) and metal impurities using chemical solutions and cleaning steps of removing unnecessary resist patterns. The cleaning steps mainly include two types of methods: a batch-type cleaning method of holding a plurality of wafers and dipping them altogether in a chemical solution tank; and a sheet-type cleaning method of transporting wafers one by one and dropping a chemical solution on each wafer.

In the sheet-type cleaning method, since the wafers are cleaned one by one, the foreign particles and contamination will not be dispersed from one wafer to another wafer. However, small local electrical discharge occurs when the cleaning chemical solution is dropped onto each wafer, and the elements and patterns formed on each wafer may be damaged. When the elements and patterns are damaged, the elements become defective elements to undesirably increase the manufacturing cost. The cause of the small electrical discharge is a potential difference between the wafer and the chemical solution due to dropping of the chemical solution on the wafer while the chemical solution and the wafer are electrically charged, thereby generating the state in which the chemical solution and the wafer are electrically charged. This electrical charge phenomenon is derived from the reasons why the wafer is electrically charged in a previous step before cleaning the wafer or the wafer is electrically charged by a friction caused when the chemical solution passes through a supply pipe.

In order to suppress such small electrical discharges caused by electrical charging, a cleaning/drying apparatus for irradiating a wafer with soft X-rays has been proposed (see Japanese Patent Laid-Open No. 8-45884). In this case, the wafer is neutralized by irradiating the electrically charged wafer with soft X-rays.

### SUMMARY OF THE INVENTION

In the technique disclosed in Japanese Patent Laid-Open No. 8-45884, a small electrical discharge generated when dropping a chemical solution on a substrate is suppressed in a sheet-type cleaning apparatus using a special apparatus or mechanism.

According to an aspect of the present invention, there is provided a technique for controlling the dropping position of a chemical solution without using a special apparatus or mechanism so as not to concentrate the small electrical discharge on one of semiconductor devices formed on a semiconductor device region, thereby improving the yield.

According to some embodiments, a method of manufacturing a semiconductor device by performing a plurality of substrate cleaning steps including a process for supplying a chemical solution on a substrate transported into a cleaning apparatus, a process for rotating the substrate, and a process for unloading the substrate from the cleaning apparatus is provided. In the plurality of cleaning steps, a dropping start position of the chemical solution on the substrate is set in a region on the substrate where the semiconductor device has been formed, and the dropping start position is changed at least once.

Further features of the present invention will become apparent from the following description of exemplary embodiments (with reference to the attached drawings).

### BRIEF DESCRIPTION OF THE DRAWINGS

FIGS. 1A and 1B are views showing the structure of a semiconductor device and a substrate surface according to an embodiment of the present invention;

FIGS. 2A to 2F are sectional views showing a semiconductor wafer as an example of a method of manufacturing a semiconductor device according to the embodiment of the present invention;

FIG. 3 is a flowchart showing an example of a method of manufacturing a semiconductor device according the embodiment of the present invention;

FIGS. 4A and 4B are views showing an arrangement of a sheet-type cleaning apparatus according to the embodiment of the present invention;

FIGS. 5A to 5C are views for explaining a cleaning method according to the first embodiment of the present invention;

FIG. 6 is a graph showing comparison of the yields of semiconductor devices by the cleaning method according to the first embodiment of the present invention;

FIGS. 7A to 7D are views showing cleaning methods according to the second, third, and fourth embodiments of the present invention;

FIGS. 8A to 8D are views for explaining cleaning methods according to the fifth, sixth, and seventh embodiments of the present invention;

FIGS. 9A and 9B are block diagrams showing an example of the arrangement of a cleaning processing system according to each embodiment of the present invention; and

FIG. 10 is a table showing an example of the data structure of a management table for managing the cleaning step of each embodiment of the present invention.

### DESCRIPTION OF THE EMBODIMENTS

### First Embodiment

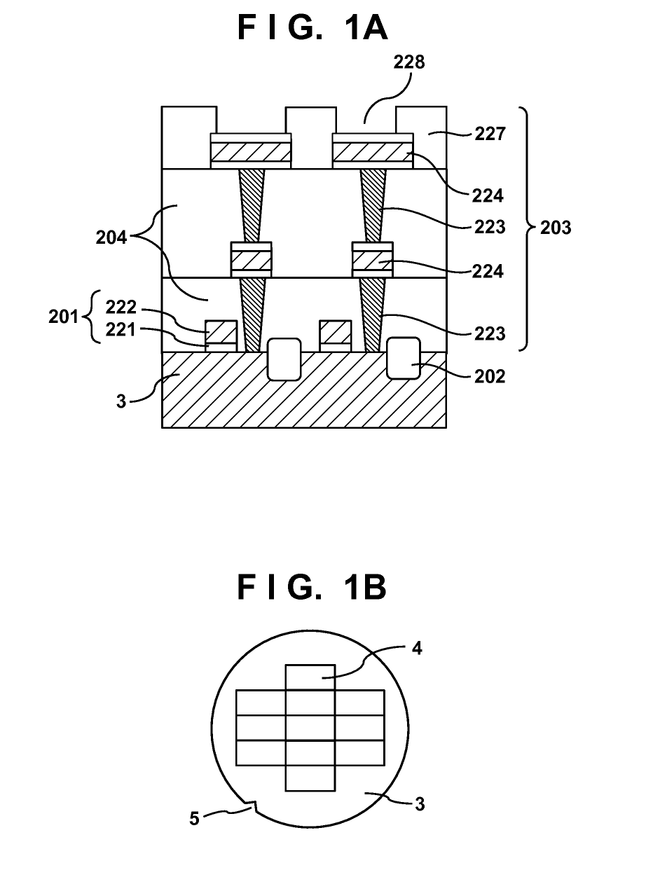

The first embodiment of the present invention will be described below. First of all, FIG. 1A shows the structure of a typical semiconductor device. The semiconductor device is formed from transistor portions 201, an element isolation portion 202, and interconnection portions 203 on the surface of a substrate 3. Each transistor portion 201 has a structure in which a gate insulating film 221 and a polysilicon film 222 are stacked on each other. Each transistor plays a role as a resistive element or a function of switching an electrical signal from the interconnection portions 203. The element isolation portion 202 is obtained by locally burying a silicon oxide film in the surface of the substrate 3 and electrically isolate the transistor portions 201 from each other. The interconnection portions 203 electrically connect the transistor portions 201 to each other or are electrically connected to external circuits. The interconnection portions 203 are formed from tungsten plugs 223 and aluminum interconnections 224. A protective layer 227 is formed on the surface layer, and opening portions 228 for exposing the aluminum interconnections are formed in parts of the protective layer 227. The protective layer 227 is formed to prevent the moisture and foreign particles from entering the interconnection portions 203 and the transistor portions 201. The opening portions 228 serve as electrode pads connected to the external circuits. Note that although the p- and n-type semiconductor regions must be formed by ion implantation in the substrate 3 shown in FIGS. 1A and 1B to obtain desired electrical characteristics, these regions are not illustrated in FIGS. 1A and 1B.

The semiconductor device shown in FIG. 1A shows a typical structure. From the viewpoint of the electrical characteristics and durability required for the semiconductor device, the present invention can be similarly applied even if the structure is different from the one described in FIG. 1A. For example, each transistor portion 201 may have a sidewall around the gate insulating film 221 and the polysilicon film 222. Alternatively, a silicide (silicon-metal compound) may be used on the surface layer of the polysilicon film 222. In this case, the semiconductor devices can serve as one semiconductor chip.

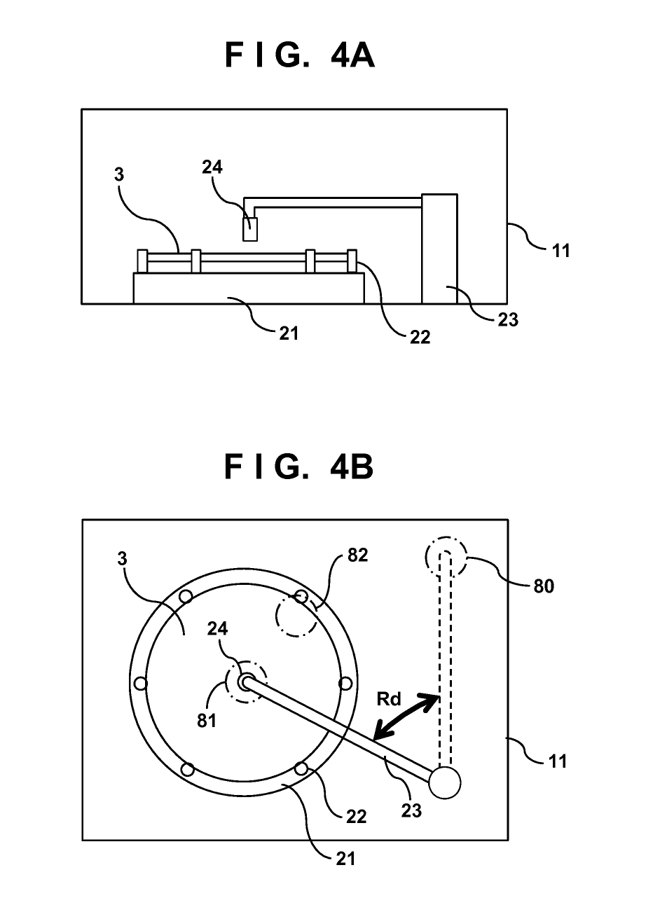

FIG. 1B shows the outer appearance of the substrate 3 on which the semiconductor device is formed. A semiconductor device region 4 is formed on the surface of the substrate 3. In the semiconductor device region 4, a plurality of semiconductor devices (corresponding to each cell) are densely arranged. The plurality of semiconductor devices can be manufactured on the substrate 3 at once. A notch 5 used for positioning is formed in the substrate 3. The notch 5 engages with a chuck pin 22 formed in a chuck base 21 in a chamber 11 in the sheet-type cleaning apparatus shown in FIGS. 4A and 4B (to be described later) to support the outer edge of the substrate 3, thereby determining the position of the substrate 3. A positioning mechanism cooperating with the notch is not limited to the chuck pin 22, but may be another mechanism. That is, a specific projecting portion to engage with the notch may be formed on the chuck base 21 other than the chuck pin 22. In addition, the notch position of the substrate 3 set when the chuck base 21 starts rotation is desirably the same position in a relative positional relationship with a predetermined reference point in the chamber. This makes it possible to always set the same notch position of the substrate 3 when the chuck base 21 starts rotation in a plurality of cleaning steps.

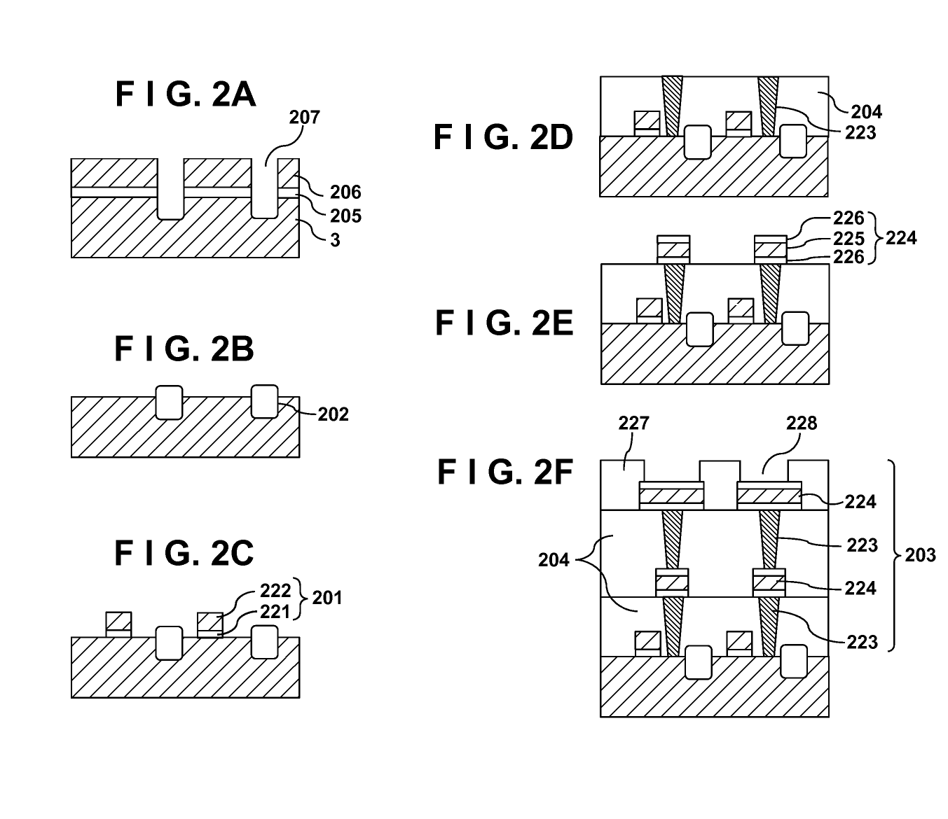

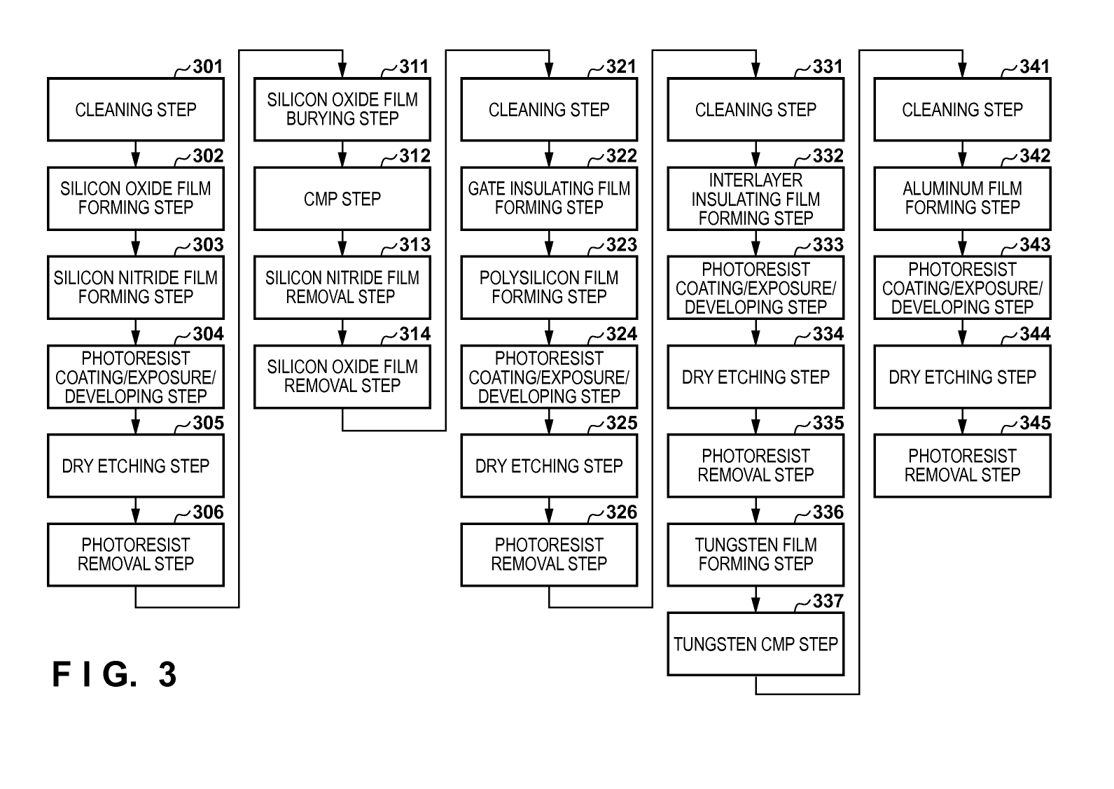

The steps in manufacturing the semiconductor device on the substrate 3 will be described with reference to FIGS. 2A to 2F. FIG. 3 is a flowchart showing the respective manufacturing steps in FIGS. 2A to 2F.

In FIG. 2A, a silicon oxide film 205 and a silicon nitride film 206 are stacked on the substrate 3. Trenches 207 are locally formed in the substrate 3. In order to form the above shape, a cleaning step 301 of removing metal contamination and particles attached to the substrate, a forming step 302 of forming the silicon oxide film 205, a forming step 303 of forming the silicon nitride film 206, an exposure and developing processing step 304 of forming a photoresist for forming a mask, a dry etching step 305, and a photoresist removal step 306 are performed.

In FIG. 2B, the silicon oxide film is buried in the trenches 207. The unnecessary silicon oxide film 205 and silicon nitride film 206 are removed, and an element isolation portion 202 is formed. In order to manufacture the above shape, a silicon oxide film forming step 311, a chemical mechanism polishing (CMP) step 312 of polishing and removing the extra silicon oxide film, a silicon nitride removal step 313, and a silicon oxide film removal step 314 are performed. The element isolation portion 202 is a region in which a buried silicon oxide film is locally formed in the substrate 3. The element isolation portion is used to electrically insulate the adjacent ones of a plurality of transistors to be formed in the subsequent process.

In FIG. 2C, each transistor portion 201 is formed in the substrate 3 in which the corresponding element isolation portion 202 is formed. In order to manufacture the above shape, a cleaning step 321 of removing the metal contamination and particles attached to the substrate, a step 322 of forming a gate insulating film 221, a step 323 of forming a polysilicon film 222, an exposure and developing processing step 324 of forming a photoresist for forming a mask, a dry etching step 325, and a photoresist removal step 326 are performed. By performing these steps, each transistor portion 201 in which the gate insulating film 221 and the polysilicon film 222 are stacked is formed. Although not shown, in order to obtain good electrical characteristics of each transistor portion, steps such as ion implantation and annealing may be performed. More specifically, generally used steps in the manufacture of the semiconductor device, such as impurity implantation into the well to obtain the p- or n-type surface of the substrate 3, source-drain impurity implantation to decrease the electrical resistance of the transistor portion, a halo implantation for suppressing hot carriers, or an annealing process for activating the ions after the ion implantation may be included.

In FIG. 2D, an interlayer insulating film 204 and tungsten plugs 223 formed inside the interlayer insulating film 204 to electrically connect the substrate 3 are formed on the surface of the substrate 3 in which the element isolation portion 202 and the transistor portions 201 are formed. In order to manufacture the above shape, a cleaning step 331 of removing the metal contamination and particles attached to the substrate 3, a step 332 of forming the interlayer insulating film 204, a coating, exposure, and developing step 333 of forming a photoresist for forming a mask, a dry etching step 334, a photoresist removal step 335, a tungsten film forming step 336, and a tungsten CMP step 337 of removing extra tungsten are performed.

In FIG. 2E, aluminum interconnections 224 are formed on the surface of the substrate 3 in which the element isolation portion 202, the transistor portions 201, and the tungsten plugs 223 are formed. The aluminum interconnections 224 can be formed from only the aluminum layers 225. However, barrier metal layers 226 may be formed on the upper and lower surfaces of each aluminum interconnection 224. This is because the barrier metal layers are used as hard masks in dry etching the aluminum layer 225 in order to suppress electromigration (the figures from FIG. 2E illustrate the barrier metal layers 226 which are formed on the upper and lower surfaces of the aluminum layer 225). Each barrier metal layer 226 is formed by, for example, a structure in which Ti and TiN are stacked. In addition, the aluminum layer 225 may contain copper or the like to lower the electrical resistance as an interconnection in addition to aluminum. In order to manufacture the above shape, a cleaning step 341 of removing the particles attached to the substrate 3, a step 342 of forming the aluminum layer 225 and the barrier metal layers 226, a coating, exposing, and developing processing step 343 of forming a photoresist for forming a mask, a dry etching step 344, and a photoresist removal step 345 are performed.

FIG. 2F shows the finished form of the semiconductor device. In FIG. 2F, the steps shown in FIGS. 2D and 2E are repeated a plurality of times to form the interconnection portions 203 in which the tungsten plugs 223 and the aluminum interconnections 224 are stacked in the interlayer insulating film 204. The number of times the tungsten plugs 223 and the aluminum interconnections 224 are stacked is performed by a necessary number of times to form circuits to obtain the required characteristics of the semiconductor devices (FIG. 2F shows the interconnection portions obtained by repeating the process two times).

The aluminum interconnection 224 as the uppermost layer is covered with the protective layer 227, and only the upper portion of the part of each aluminum interconnection is exposed in the corresponding opening portion 228. Each opening portion 228 serves as a portion to be electrically connected by wire bonding when the semiconductor device is connected to an external circuit. The semiconductor device is manufactured on the substrate 3 through the above steps.

As shown in FIG. 3, the manufacture of semiconductor devices has a plurality of cleaning steps 301, 321, 331, and 341. The present invention is applicable to all the cleaning steps using a sheet-type cleaning apparatus (to be described later). The present invention is also applicable to a step using a sheet-type cleaning apparatus except the cleaning steps described in the above embodiment. For example, the present invention is applicable to a case in which a sheet-type cleaning apparatus is used for a photoresist removal step using a predetermined removal solution.

The structure and operation of a sheet-type cleaning apparatus for practicing cleaning steps necessary in the present invention will be described below. FIG. 4A shows the structure of a chamber inside the sheet-type cleaning apparatus. In the sheet-type cleaning apparatus, the substrate 3 is transported to the chamber 11 using a transport robot (not shown) from the outside. The chamber 11 has a mechanism for supporting and rotating the transported substrate 3. In the chamber 11, a process for dropping a chemical solution onto the supported substrate 3 and dipping the entire substrate in the chemical solution can be performed. A chuck base 21 is provided in the chamber 11 so that the substrate 3 can be placed on the chuck base 21. The chuck base 21 includes chuck pins 22 for supporting the edge of the substrate 3. The chuck base 21 can rotate while supporting the substrate 3. A chemical solution nozzle 23 serving as a cleaning portion for dropping the chemical solution onto the surface of the substrate 3 to clean it is arranged near the chuck base 21. The chemical solution nozzle 23 has a tube for carrying the chemical solution. The chemical solution is pressurized by a chemical solution tank (not shown) outside the chamber 11 to be carried to the chemical solution nozzle 23. The chemical solution is dropped on the substrate 3 from a dropping port 24 located at the distal end of the chemical discharge nozzle. Although not shown, a pure water nozzle for dropping pure water to remove the chemical solution from the substrate 3 is also provided.

FIG. 4B is a view showing an example of motion of the chemical solution nozzle 23 when illustrating the inside of the chamber 11 from the upper surface. By using an installation position 401 of the chemical solution nozzle 23 on the chuck base 21 as a reference, the chemical solution nozzle 23 has a mechanism which turns in a direction parallel to the substrate 3 to be processed. A dropping port 24 for dropping the chemical solution normally falls within a standby position 80. The turning mechanism can move the dropping port 24 to a central position 81 on the flat surface of the substrate 3 or a peripheral portion 82. The dropping port 24 can also move to a peripheral portion which is opposite to the peripheral portion 82 and exceeds the central position 81. The chemical solution nozzle 23 turns the dro2pping port 24 to a desired position such as the central position 81 of the substrate. The chemical solution is supplied from the chemical solution tank and can be dropped onto the surface of the substrate 3 from the dropping port 24. The above-described pure water nozzle is also provided in the chamber 11 and can drop the pure water onto the surface of the substrate 3 by a turning mechanism similar to that of the chemical solution nozzle 23.

In this embodiment, the dropping start position of the chemical solution is set at one of different positions on the chuck base 21. Since the chemical solution nozzle 23 turns about the installation position 401, the dropping start position can be expressed by a rotation angle Rd from the standby position 80 of the chemical solution nozzle 23. Note that Rd has a value falling within the range in which a semiconductor device is formed on the substrate 3. Instead of the rotation angle, the dropping start position of the chemical solution may be expressed by coordinates (x, y) in a two-dimensional coordinate system having, for example, the center of the chuck base 21 as the origin.

The operation of the plurality of cleaning steps performed in the sheet-type cleaning apparatus will be described in detail below. The first cleaning step is performed in steps (1) to (7) below:
(1) the substrate 3 is transported onto the chuck base 21, and aligned and fixed;
(2) the dropping port 24 is moved to the central position 81 of the substrate 3;
(3) the substrate 3 is rotated in the planar direction;
(4) the chemical solution is dropped at the central position 81 on the surface of the substrate 3 from the dropping port 24 for a predetermined period of time;
(5) the pure water is dropped from the pure water nozzle onto the surface of the substrate 3 to remove the chemical solution;
(6) the rotation speed of the substrate 3 is increased to remove the pure water attached to the substrate 3 to dry the substrate 3; and
(7) The substrate 3 is removed from the chuck base 21 and unloaded outside the chamber 11.

In this embodiment, the cleaning step is performed in the order of steps (1) to (7). However, the effect of the present invention can be attained even if the order of the steps is not limited to this. For example, step (4) may be repeated a plurality of times. The start of rotation in step (3) may be performed after step (4).

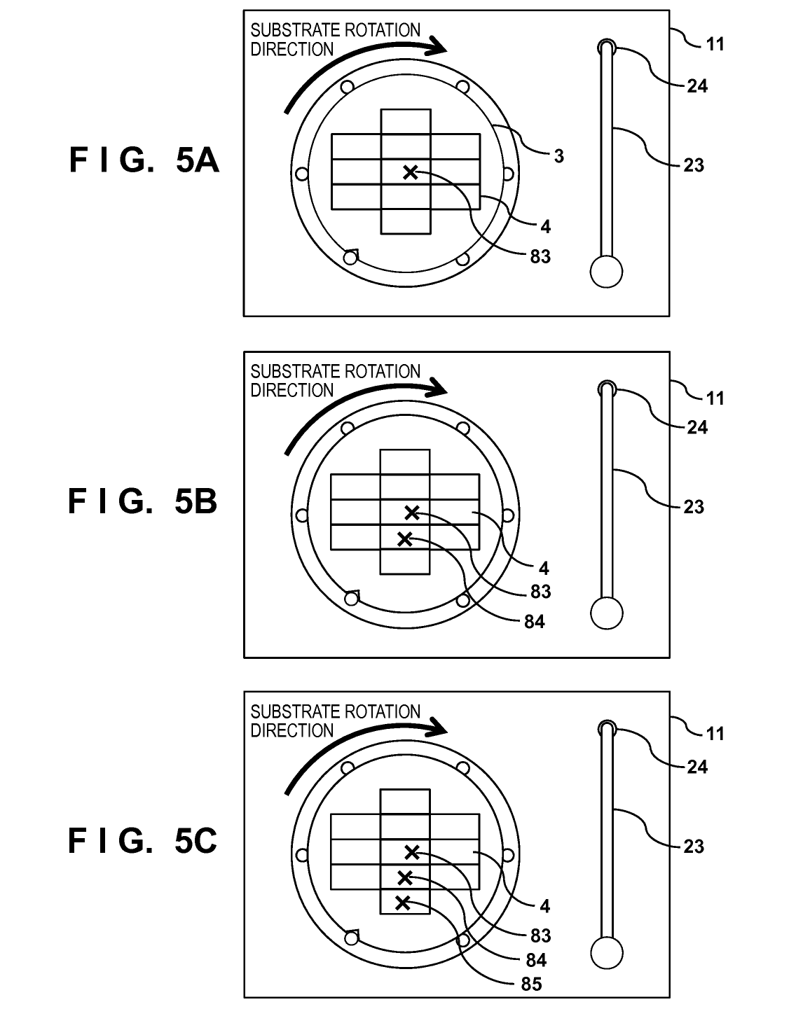

A cleaning method in the sheet-type cleaning apparatus according to this embodiment of the present invention will be described in detail below. FIGS. 5A to 5C are views for explaining the cleaning method. First of all, FIG. 5A illustrates, from the upper surface, the chamber 11 formed in the sheet-type cleaning apparatus based on FIG. 4B. The semiconductor device region 4 having a predetermined structure obtained up to an arbitrary step out of the manufacturing steps in forming the semiconductor devices are formed in the surface of the substrate 3. The substrate 3 is transported from the outside by the transport robot, aligned based on the notch 5, supported by the chuck pins 22, and rotated in the planar direction indicated by an arrow. The rotation speed of the substrate 3 can be a rotation speed which allows the dropped chemical solution to uniformly spread on the entire surface of the substrate 3. The rotation speed falls within the range of, for example 100 rpm to 2,000 rpm.

In the first cleaning step achieved by the sheet-type cleaning apparatus, the dropping port 24 is located at a first dropping position 83 above an upper portion of the semiconductor device region 4 on the substrate 3 by the turning operation of the chemical solution nozzle 23. The first dropping position 83 can be a position at which the entire surface of the substrate 3 is covered with the chemical solution when dropping the chemical solution on the surface of the rotating substrate 3, for example, almost the center or its vicinity on the surface of the substrate 3. After that, the chemical solution is dropped at the first dropping position 83 from the dropping port 24 onto the substrate 3 to bring the dropped chemical solution into contact with the semiconductor device region 4 on the substrate 3. The chemical solution is continuously dropped for a desired period of time and stopped. Subsequently, pure water is dropped from the pure water nozzle onto the substrate 3 to remove the chemical solution attached to the substrate 3. After the pure water is dropped for a period of time required for removing the chemical solution, dropping of the pure water is stopped. After that, the substrate 3 is rotated at a rotation speed of 1,000 rpm to 3,000 rpm to dry the substrate 3, thereby removing the pure water. The substrate 3 is then unloaded from the chamber 11 by the transport robot, thereby completing the first cleaning step (step 301 in FIG. 3). As shown in FIG. 3, after the end of the first cleaning step 301, the process reaches the second cleaning step 321 when the substrate 3 has undergone steps such as forming a film, photolithography, and dry etching in other apparatuses.

A method of practicing the second cleaning step 321 will be described with reference to FIG. 5B. In FIG. 5B, the substrate 3 is placed and rotated in the same manner as in the first cleaning step 301 described in FIG. 5A. The dropping port 24 is moved to a second dropping position 84 above the semiconductor device region 4 on the substrate 3 by turning the chemical solution nozzle 23. The second dropping position 84 may be any position when the position is located on the semiconductor device region 4 and different from the first dropping position 83. The dropping position 84 in FIG. 5B is illustrated to be located on a specific semiconductor device on the substrate 3, but this does not mean that the chemical solution is dropped at this position on the substrate 3. The second dropping position 84 indicates the position of the dropping port 24 at the start of dropping in relation to the chuck base 21. This also applies to a figure in which the chemical solution is dropped on the rotating substrate 3. The chemical solution is dropped at the dropping position 84 to clean the entire surface of the substrate 3 with the chemical solution. In this case, since the second dropping position 84 is different from the first dropping position 83, the position at which the chemical solution contacts the flat surface of the substrate 3 at the start time of dropping the chemical solution is different between the first cleaning step and the second cleaning step. The removal of the chemical solution by the pure water dropping and drying of the substrate 3 are performed in the same manner as in the first cleaning step 301, thereby completing the second cleaning step 321.

A method of performing cleaning steps from the third cleaning step will be described with reference to FIG. 5C. The position of the dropping port 24 in FIG. 5C is illustrated as an nth dropping position 85 different form those in FIGS. 5A and 5B. The subsequent process is the same as in the above first cleaning step. The chemical solution is dropped at the nth dropping position which is located on the semiconductor device region 4 and different from the dropping position in the (n−1)th cleaning step (if the dropping position is set for the fifth cleaning step, the fifth dropping position is different from the first to fourth dropping positions). In this case, since the nth dropping position is different from the dropping positions of the previous cleaning steps, the positions at which the chemical solution contacts on the flat surface of the substrate 3 first are different in the plurality of cleaning steps.

As described above, according to the feature of this embodiment, in the semiconductor device manufacturing process including a plurality of cleaning steps, the position at which the chemical solution drops on the surface of the substrate 3 first is set as a position on the semiconductor device region 4, and the dropping start positions are different in the respective cleaning steps. In order to reliably set different dropping positions on the semiconductor device region 4, the rotation speed of the substrate 3 and the standby time from the start of rotation to the start of dropping can be kept unchanged in the respective cleaning steps. Since the substrate 3 is aligned at a predetermined position by the notch 5 on the chuck base 21 in a plurality of cleaning steps, and the rotation speed and the standby time are kept unchanged in the respective steps, even if the chemical solution is dropped on the rotating substrate 3, the chemical solution can be dropped at different positions. In particular, even if the dropping port 24 of the chemical solution nozzle 23 is located at different positions on the chuck base 21, and radial distances from the center (rotation center) of the substrate are equal to each other, the chemical solution can be dropped at different positions on the substrate 3.

In the embodiment described above, a small electrical discharge generated as soon as the chemical solution is dropped and contacts the substrate 3 first is not concentrated on one of the semiconductor devices formed in the semiconductor device region 4. Since the pattern damage and electrostatic breakdown of a semiconductor device are not concentrated on one semiconductor device, the yield can be improved. In addition, since the dropping start position is set on the semiconductor device region, the chemical solution dropped on the chuck pins 22 which support the substrate 3 will not contact and scatter, and the scattered chemical solution will not contaminate the interior of the chamber 11 or degrade the parts in the chamber 11. Accordingly, maintainability of the sheet-type cleaning apparatus can be improved, and the maintenance cost can be set low. In addition, since a special mechanism such as a soft X-ray generation apparatus need not be provided, the apparatus will not have a large scale.

Although different dropping positions are used in all the plurality of cleaning steps in this embodiment, the different dropping positions need not always be used in the cleaning steps in all the sheet-type cleaning apparatuses included in the manufacturing process. In the plurality cleaning steps, the dropping position is made different at least once from the dropping positions in other cleaning steps, thereby obtaining the effect of the present invention.

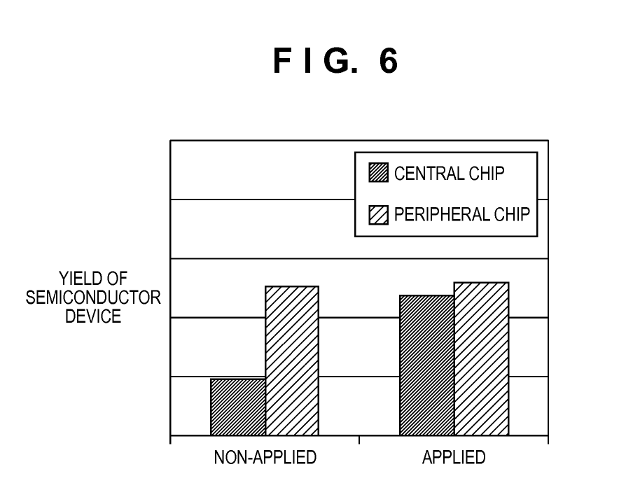

The effect obtained by this embodiment is shown in FIG. 6. FIG. 6 shows the comparison between the yield when the present invention is applied to the formation of semiconductor devices on a silicon wafer and the yield when the present invention is not applied to this. “Not-applied” in FIG. 6 indicates that a cleaning step is performed when the chemical solution dropping position in the sheet-type cleaning apparatus is set as the central portion of the surface of the wafer. “Applied” indicates that the cleaning step is performed such that the chemical solution dropping positions on the surface of the wafer are different in the respective cleaning steps. In order to verify the effect of the present invention, the wafer positions are classified into a “central chip” and a “peripheral chip”. In “not-applied”, the yield is lower in the “central chip” than in the “peripheral chip”. In “applied”, obviously, the yield in the “central chip” is improved to be almost equal to that in the “peripheral chip”.

According to this embodiment, the chemical solution is dropped in one cleaning step, and an operation for stopping dropping the chemical solution after a predetermined period of time is performed once. However, even if the chemical solution is dropped several times during one cleaning step, the effect of the present invention can be obtained. In this case, by setting different dropping positions for the plurality of chemical solution dropping operations during one cleaning step, the effect of the present invention can be further enhanced.

The cleaning method corresponding to this embodiment (this also applies to subsequent embodiments) may be applied to cleaning steps 331 and 341 performed particularly for formation of the transistors 201 and the subsequent steps out of the manufacturing steps of the semiconductor devices described from FIG. 2A to FIG. 2F. In this case, a small electrical discharge generated when the chemical solution contacts the substrate 3 in the cleaning step will not be concentrated on one semiconductor device. Electrostatic breakdown caused by the electrical discharge acting on the transistor portion may not be generated by the cleaning processing upon formation of the transistor portion, thereby improving the yield of the semiconductor devices.

### Second Embodiment

The second embodiment of the present invention will be described below. This embodiment is applied to the cleaning step performed in the manufacturing process of semiconductor devices based on the first embodiment, and processing in the cleaning step is embodied. The arrangement of a sheet-type cleaning apparatus for performing the cleaning step is the same as in FIGS. 4A and 4B.

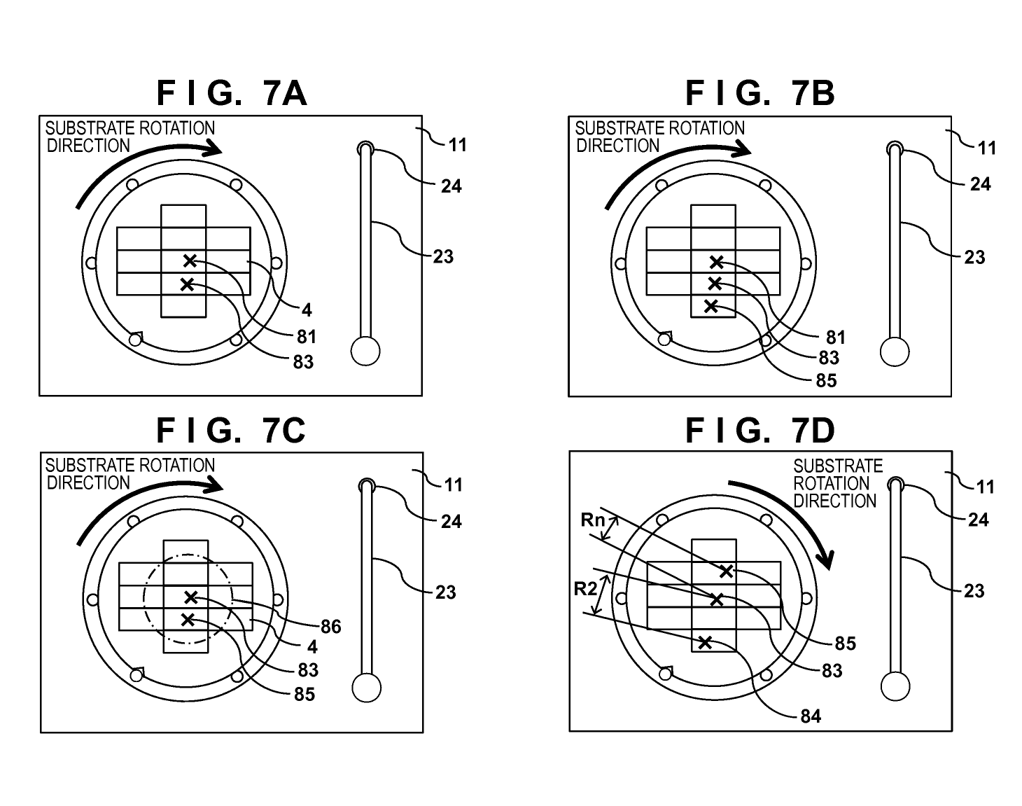

FIGS. 7A and 7B are views showing the interior of the sheet-type cleaning apparatus for explaining the cleaning method according to this embodiment. FIG. 7A illustrates a chamber 11 in the sheet-type cleaning apparatus from the upper surface as in FIG. 5A. A substrate 3 aligned based on a notch 5 is supported by chuck pins 22 and is rotating in a planar direction indicated by an arrow. In the first cleaning step of this embodiment, a dropping port 24 is aligned at a first dropping position 83 located on a semiconductor device region 4 of the substrate 3 by turning a chemical solution nozzle. In the first cleaning step of this embodiment, the chemical solution is dropped on the substrate 3 from the dropping port 24 located at the first dropping position 83. While dropping of the chemical solution is kept continued, a chemical solution nozzle 23 is turned to move the dropping port 24 toward the central direction (central position 81) on the surface of the substrate 3. The dropping position 83 is an arbitrary position on the semiconductor device region 4 if it is shifted from the central position 81 on the surface of the substrate 3. The chemical solution is dropped for a desired period of time and stopped. Dropping of pure water, drying by the rotation of the substrate 3, and unloading of the substrate 3, which will be performed subsequently, are the same as in the method described in the first embodiment, and a description thereof will be omitted. The first cleaning step (step 301 in FIG. 3) has been completed.

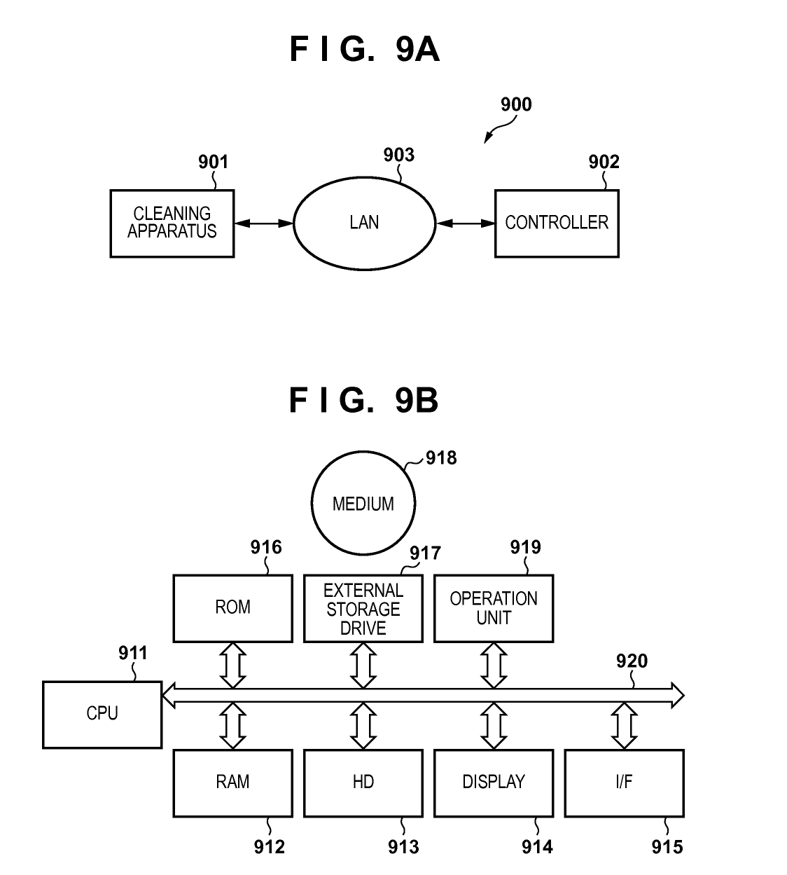

As shown in FIG. 3, after the end of a first cleaning step 301, the substrate 3 is subjected to steps such as forming a film, photolithography, dry etching in other apparatuses. The process then advances to a second cleaning step 321. A method from the second cleaning step will be described with reference to FIG. 7B. FIG. 7B is the same as in FIG. 9A except that the position of the dropping port 24 is located at an nth dropping position 85 unlike in FIG. 7A. The nth dropping position 85 is an arbitrary position which is located on the semiconductor device region 4 and different from the position of the dropping port 24 in the previous (n−1)th cleaning step (for example, the first to fourth dropping positions if the current dropping position is the fifth dropping position). Subsequently, while the chemical solution is kept dropped, the chemical solution nozzle 23 is turned to move the dropping port 24 to the central position 81 on the surface of the substrate 3. The chemical solution is kept dropped for a desired period of time and stopped. The process to be performed after cleaning by the chemical solution is the same as in the first cleaning solution, and a description thereof will not be repeated. The process then advances to the second cleaning step and the subsequent cleaning steps. Note that to reliably set different dropping positions on the semiconductor device region 4, the rotation speed of the substrate 3 and the standby time from the start of rotation to the start of dropping are kept unchanged in each step as in the first embodiment.

As described above, according to the feature of this embodiment, in the semiconductor device manufacturing process having a plurality of cleaning steps, the position at which the chemical solution is dropped first on the surface of the substrate 3 is located on the semiconductor device region 4, the chemical solution nozzle 23 is turned to the central position of the substrate 3 while the chemical solution is kept dropped, and different chemical solution dropping start positions are used in the cleaning steps, respectively. This makes it possible to prevent a small electrical discharge generated when the chemical solution contacts the substrate 3 from being concentrated on one of the semiconductor devices formed on the semiconductor device region 4, thereby improving the yield of the semiconductor devices. In addition, since the chemical solution nozzle 23 is turned while the chemical solution is kept dropped, and the dropping port 24 is moved to the central position 81 on the surface of the substrate 3, cleaning and etching on the surface of the substrate 3 are uniformly performed on the entire surface of the substrate 3.

### Third Embodiment

The third embodiment of the present invention will be described below. This embodiment is applied to the cleaning steps performed in the manufacturing process of semiconductor devices according to the first and second embodiments. The processes in the cleaning steps are embodied. The arrangement of a sheet-type cleaning apparatus for performing the cleaning steps is also the same as in FIGS. 4A and 4B.

FIG. 7C is a view showing the interior of the sheet-type cleaning apparatus for explaining the cleaning method according to the third embodiment. FIG. 7C illustrates a chamber 11 in the sheet-type cleaning apparatus from the upper surface as in FIG. 5A. A substrate 3 aligned based on a notch 5 is supported by chuck pins 22 and is rotating in a planar direction indicated by an arrow. In the first cleaning step of this embodiment, a dropping port 24 is aligned at a first dropping position 83 located on a semiconductor device region 4 of the substrate 3 by turning a chemical solution nozzle. The first dropping position 83 is set at a position included in a region 86 near the center of the surface of the substrate 3 and is not limited to the central position on the surface of the substrate 3. The chemical solution is kept dropped for a desired period of time and stopped. Dropping of pure water, drying by the rotation of the substrate 3, and unloading of the substrate 3, which will be performed subsequently, are the same as in the method described in the first embodiment, and a description thereof will be omitted. The first cleaning step has been completed.

As shown in FIG. 3, after the end of a first cleaning step 301, the substrate 3 is subjected to steps such as forming a film and dry etching in other apparatuses. The process then advances to a second cleaning step 321. The second or subsequent cleaning step is the same as the first cleaning step except that the position of the dropping port 24 is located at an nth dropping position 85 different from the first dropping position 83. The nth dropping position 85 is given as a position included in the region 86 near the center of the substrate 3. Note that to reliably set different dropping positions on the semiconductor device region 4, the rotation speed of the substrate 3 and the standby time from the start of rotation to the start of dropping are kept unchanged in each step as in the first embodiment.

According to the feature of the cleaning steps of this embodiment, the dropping port 24 is located in the semiconductor device region 4 on the surface of the substrate 3 while the chemical solution is being dropped, and the dropping port 24 is set at the position (position within the region 86) within the region near the center of the substrate 3. According to the feature of this embodiment, different dropping start positions are set in the cleaning steps, respectively. When this embodiment is used, the chemical solution dropped on the substrate 3 uniformly contacts the entire surface of the substrate 3, and therefore desired effects such as cleaning and etching can be uniformly performed on the entire substrate 3. In addition, the dropped chemical solution can be prevented from being scattered by the chuck pins 22 which support the substrate 3 and from being accidentally exposed in the chamber 11. Therefore, the parts and devices in the chamber 11 will not be degraded by the chemical solution.

Note that the region 86 near the center in this embodiment can be the range capable of obtaining desired effects (for example, an etching film thickness, uniformity of a foreign material removal effect on the wafer surface, and scattering of the chemical solution). Sufficient effects can be obtained if the region 86 falls within the range of, for example, ½ to ¼ the radius of the substrate 3.

### Fourth Embodiment

The fourth embodiment of the present invention will be described below. This embodiment is applied to the cleaning steps performed in the manufacturing process of semiconductor devices according to the first to third embodiments. The processes in the cleaning steps are embodied. The arrangement of a sheet-type cleaning apparatus for performing the cleaning steps is also the same as in FIGS. 4A and 4B.

FIG. 7D is a view showing the interior of the sheet-type cleaning apparatus for explaining the cleaning method according to the fourth embodiment. FIG. 7D illustrates a chamber 11 in the sheet-type cleaning apparatus from the upper surface as in FIG. 5A. A substrate 3 aligned based on a notch 5 is supported by chuck pins 22 and is rotating in a planar direction in FIG. 7D. In the first cleaning step of this embodiment, a dropping port 24 is aligned at a first dropping position 83 located on a semiconductor device region 4 of the substrate 3 by turning a chemical solution nozzle. The chemical solution is dropped on the substrate 3 from the dropping port 24 located at the first dropping position 83. The chemical solution is kept dropped for a desired period of time and stopped. Dropping of pure water, drying by the rotation of the substrate 3, and unloading of the substrate 3, which will be performed subsequently, are the same as in the method described in the first embodiment, and a description thereof will be omitted. The first cleaning step has been completed. As shown in FIG. 3, after the end of a first cleaning step 301, the substrate 3 is subjected to steps such as forming a film and dry etching in other apparatuses. The process then advances to a second cleaning step 321.

In the second or subsequent cleaning step, the position of the dropping port 24 is located at an nth dropping position 85. The nth dropping position 85 is located on the semiconductor device region 4 and is determined as a radial position of the substrate 3 different from the position of the dropping port 24 in the previous (n−1)th cleaning step (for example, the first to fourth dropping positions if the current dropping position is the fifth dropping position).

More specifically, in FIG. 7D, letting R1 be an interval from the center on the surface of the substrate 3 to the first dropping position 83 (not shown, but R1=0 in FIG. 7D), R2 be an interval from the central position on the surface of the substrate 3 to the second dropping position 84, and Rn be an interval from the central position on the surface of the substrate 3 to the nth dropping position 85, the dropping positions are determined such that R1, R2, . . . , Rn are different from each other.

After the dropping port 24 is moved to the nth dropping position 85, the chemical solution is dropped. After the chemical solution is dropped for a desired period of time, dropping of the chemical solution is stopped, removal of the chemical solution by dropping pure water after cleaning with the chemical solution, and drying by the rotation of the substrate 3 are performed as in the first cleaning step.

According to the feature of the cleaning steps of this embodiment, the dropping port 24 is located in the semiconductor device region 4 on the surface of the substrate 3 while the chemical solution is being dropped, and different dropping start positions are set in cleaning steps, respectively, in the radial direction. The positions are determined as described above due to the following reason. When the distances from the center are equal to each other even if the dropping positions are different from each other, the chemical solution may be dropped at the same position because the substrate is being rotated. According to this embodiment, the dropping positions are different from each other in the radial direction, and the chemical solution will not be dropped at the same position on the rotating substrate 3. Note that to reliably set different dropping positions on the semiconductor device region 4, the rotation speed of the substrate 3 and the standby time from the start of rotation to the start of dropping are kept unchanged in each step as in the first embodiment. In addition, according to the method of this embodiment, the dropping positions on the semiconductor device region 4 can be reliably made different from each other even if the substrate 3 is not aligned.

According to this embodiment as well, this makes it possible to prevent a small electrical discharge generated when the chemical solution contacts the substrate 3 from being concentrated on one of the semiconductor devices formed on the semiconductor device region 4, thereby improving the yield of the semiconductor devices. Since different dropping positions are set in the cleaning steps, respectively, in the radial direction on the surface of the substrate 3, a special mechanism or modification of a sheet-type cleaning apparatus which performs the cleaning steps need not be implemented, thereby preventing the apparatus from a large scale.

### Fifth Embodiment

The fifth embodiment of the present invention will be described below. This embodiment is applied to cleaning steps to be performed in the manufacturing process of semiconductor devices according to the first to fourth embodiments. The processes in the cleaning steps are embodied. The arrangement of a sheet-type cleaning apparatus for performing cleaning steps is the same as in FIGS. 4A and 4B.

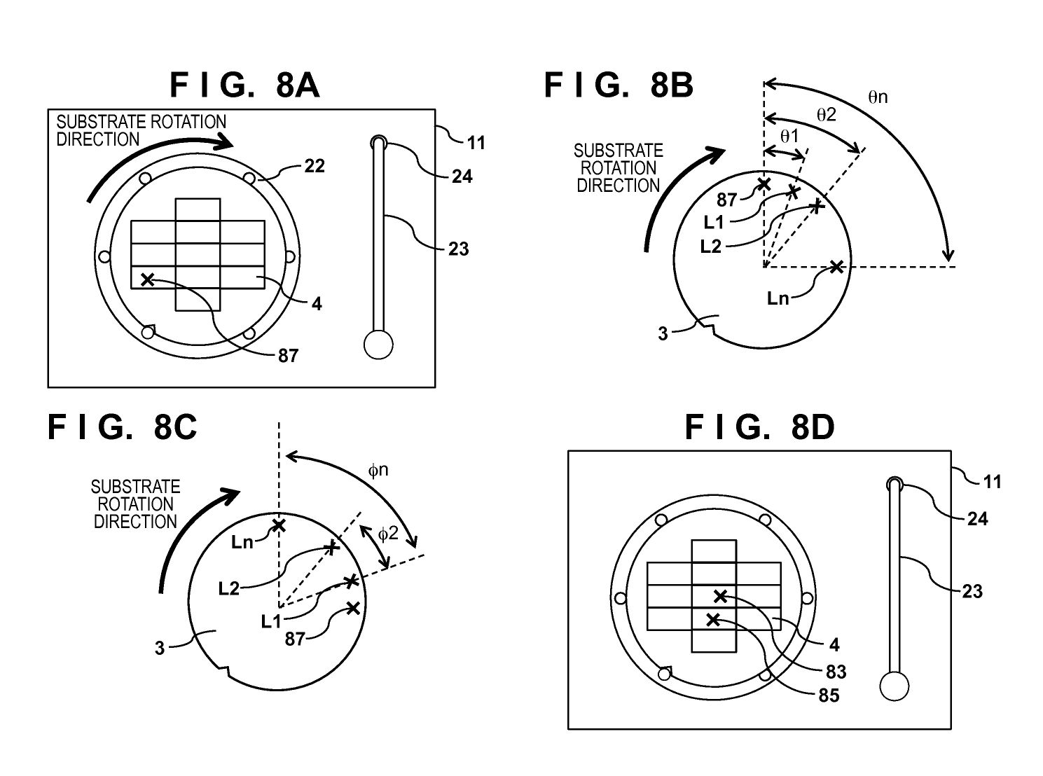

FIG. 8A shows the interior of the sheet-type cleaning apparatus for explaining a cleaning method according to this embodiment. FIG. 8A illustrates a chamber 11 in the sheet-type cleaning apparatus from the upper surface as in FIG. 5A. A substrate 3 aligned based on a notch 5 is supported by chuck pins 22 and is rotating in a planar direction indicated by an arrow. In the first cleaning step of this embodiment, a dropping port 24 is aligned at a dropping position 87 located above an upper portion of a semiconductor device region 4 of the substrate 3 by turning a chemical solution nozzle.

In the first cleaning step of this embodiment, the substrate 3 is fixed by chuck pins 22 and is rotating at a substrate rotation speed F1 [rpm]. The rotation speed is determined in the range in which the chemical solution uniformly spreads when the chemical solution is dropped or the dropped chemical solution does not scatter upon contact with the chuck pins 22. The rotation speed may fall within the range of 30 rpm to 1,000 rpm.

The chemical solution is dropped on the substrate 3 from the dropping port 24 located at the dropping position 87. The chemical solution is dropped for a desired period of time and stopped. Dropping of pure water, drying by the rotation of the substrate 3, and unloading of the substrate 3, which will be performed subsequently, are the same as in the method described in the first embodiment, and a description thereof will be omitted. The first cleaning step has been completed.

As shown in FIG. 3, after the end of the first cleaning step 301, the process reaches the second cleaning step 321 when the substrate 3 has undergone steps such as forming a film and dry etching in other apparatuses. The second or subsequent cleaning step will be described with reference to FIG. 8A in the same manner as in the first cleaning step. The substrate 3 is fixed by the chuck pins 22 and is rotating at a rotation speed Fn different from those of the previous cleaning steps. Fn is the rotation speed of the substrate 3 in the nth cleaning step, and n indicates the processing order of the cleaning steps (for example, the rotation speed of the substrate 3 in the first cleaning step is F1, and the rotation speed of the substrate 3 in the second cleaning step is F2). In this case, the rotation speeds F1, F2, . . . , Fn have different values, respectively. That is, according to the feature of this embodiment, the rotation speeds of the substrate 3 are different in the cleaning steps, respectively.

The chemical solution is dropped on the substrate 3 rotated at the substrate speed Fn from the dropping port 24 located at the dropping position 87. The chemical solution is dropped for a desired period of time and is stopped. Removal of the chemical solution by dropping of pure water upon completion of cleaning with the chemical solution and drying by the rotation of the substrate 3 are performed in the same manner as in the first cleaning step.

According to the feature of this embodiment, the dropping start position is located on the semiconductor device region 4, and the rotation speeds of the substrate 3 when dropping the chemical solution from the dropping port 24 to the rotating substrate 3 are different from each other in the cleaning steps, respectively.

Note that to reliably set different dropping positions on the semiconductor device region 4, the standby time from the start of rotation of the substrate 3 to the start of dropping is kept unchanged in each step as in the first embodiment. In addition, the rotation speeds F1 to Fn are particularly set to satisfy a relation in which the rotation speed from the start of rotation to the start of dropping in relation to the standby time is a multiple or divisor. For example, assume that F1 is 60 rpm, F2 is 120 rpm, and the standby time is 1 sec. Note that the time from the start of rotation to a rise time until the rotation speed is stabilized is neglected for the descriptive simplicity. When the rotation speed is F1, one revolution of the substrate 3 reaches the dropping start timing. When the rotation speed is F2, two revolutions of the substrate 3 reach the dropping start timing. In this case, a detailed example will be described with reference to FIG. 8B.

FIG. 8B is a view for explaining the relationship between the chemical solution dropping positions and positions at which the chemical solution contacts the substrate 3 in a plurality of cleaning steps. As in FIG. 8A, although the semiconductor device region 4 is formed on the substrate 3, the semiconductor device region 4 is not illustrated because the positions at which the chemical solution contacts on the substrate 3 are explicitly indicated in FIG. 8B. In FIG. 8B, the dropping port 24 (not shown) located on the substrate is fixed to the dropping position 87. Let L1 be a position at which the chemical solution contacts the substrate 3 when the rotation speed is set at the substrate rotation speed F1, L2 be a position at which the chemical solution contacts the substrate 3 when the rotation speed is set at the substrate rotation speed F2, and Ln be a position at which the chemical solution contacts the substrate 3 when the rotation speed is set at the substrate rotation speed Fn. Also let θn [°] be an angle formed by the dropping position 87, the substrate center O, and the dropping position Ln. For example, an angle formed by the dropping position 87, the substrate center, and L1 is given as θ1.

When the chemical solution is dropped on the substrate 3 from the dropping port 24 located at the dropping position 87, a predetermined distance is set between the dropping port 24 and the substrate 3. A short time is generated from the start of dropping to the contact with the substrate 3. Letting t [sec] be a time from the start of dropping to the contact with the substrate 3, the substrate rotation speed Fn and θn have a relation given by:

θn=t×(Fn/60)×360(0°≦θn<360°)

When the substrate rotation speed changes, different rotation speeds of the substrate 3 are set from the start of dropping on the rotating substrate 3 to the contact with the substrate 3, so that positions L1, L2, . . . , Ln when the chemical solution contacts the substrate 3 are different from each other. FIG. 8B shows condition F1<F2<Fn, so that θ1<θ2<θn is given. Therefore, the positions at which the dropped chemical solution contacts the substrate 3 are positions apart from the dropping position 87 in the order of L1, L2, and Ln.

When the above embodiment is used, small electrical discharges generated when the chemical solution contacts the substrate 3 in the plurality of cleaning steps can be generated at different positions of the substrate 3. The small electrical discharge will not be concentrated on one of the semiconductor devices formed on the semiconductor device region 4, thus improving the yield of the semiconductor devices. Note that although the dropping position 87 in FIGS. 8A and 8B is fixed regardless of the order of cleaning steps, different dropping positions 87 may be set in cleaning steps, respectively, thus obtaining the same effect as described above.

### Sixth Embodiment

The sixth embodiment of the present invention will be described below. This embodiment is applied to cleaning steps to be performed in the manufacturing process of semiconductor devices according to the first to fourth embodiments. The processes in the cleaning steps are embodied. The arrangement of a sheet-type cleaning apparatus for performing cleaning steps is the same as in FIGS. 4A and 4B.

This embodiment will be described with reference to FIG. 8A in the same manner as in the fifth embodiment. In the first cleaning step, the arrangement of a sheet-type cleaning apparatus is the same as in the fifth embodiment. In the first cleaning step of this embodiment, when the rotation of a substrate 3 starts and a predetermined standby time T1 [sec] has elapsed, the chemical solution is dropped on the substrate 3 from a dropping port 24 located at a dropping position 87. The standby time T1 may be 0.5 sec to 10 sec because the time is set so that the rotation speed of the substrate reaches a sufficient stable rotation speed. Dropping of pure water, drying by the rotation of the substrate 3, and unloading of the substrate 3, which will be performed subsequently, are the same as in the method described in the first embodiment, and a description thereof will be omitted. The first cleaning step has been completed. As shown in FIG. 3, after the end of the first cleaning step 301, the process reaches the second cleaning step 321 when the substrate 3 has undergone steps such as forming a film and dry etching in other apparatuses. The process advances to a second cleaning step 321.

The second or subsequent cleaning step will be described with reference to FIG. 8A in the same manner as in the first cleaning step. The substrate 3 fixed by chuck pins 22 starts rotation, and a standby time Tn [sec] different from that in the previous cleaning steps has elapsed. The chemical solution is dropped on the substrate 3 from the dropping port 24 located at the dropping position 87. n indicates the processing order of cleaning steps (for example, the standby time in the first cleaning step is represented by T1, and the standby time in the second cleaning step is represented by T2). The subsequent dropping of pure water after the chemical solution is dropped, drying by the rotation of the substrate 3, and unloading of the substrate 3 are performed in the same manner as in the first cleaning step.

According to the feature of this embodiment, the standby times from the start of the rotation of the substrate 3 to the dropping of the chemical solution from the dropping port 24 are different from each other in the plurality of cleaning steps. This feature will be described in detail with reference to FIG. 8C. FIG. 8C shows the relationship between chemical solution dropping positions and positions at which the chemical solution contacts the substrate 3 in the plurality of cleaning steps (as in FIG. 8B, although the semiconductor device region 4 is formed on the substrate 3, the semiconductor device region 4 is not illustrated to explicitly indicate the positions at which the chemical solution contacts on the substrate 3). FIG. 8C describes a case in which the dropping port 24 (not shown) located on the substrate is fixed to the dropping position 87 and the rotation speed of the substrate 3 is kept unchanged in the respective cleaning steps. Let L1 be a position at which the chemical solution contacts the substrate 3 when the standby time is set as the standby time T1, L2 be a position at which the chemical solution contacts the substrate 3 when the standby time is set as the standby time T2, and Ln be a position at which the chemical solution contacts the substrate 3 when the standby time is set as the standby time Tn. Also let φn [°] be an angle formed by L1, the substrate center, and Ln (for example, an angle formed by L1, the substrate center, and L2 is given by φ2).

Letting F [rpm] be a rotation speed of the substrate 3, the standby time Tn and φn have a relation given by:

φn=(Tn−T1)×(F/60)×360(0°≦φn<360°)

When the standby time Tn changes, the position L1 at which the chemical solution contacts the substrate 3 in the first cleaning step is different from the subsequent contact positions L2, . . . , Ln. FIG. 8C shows condition T1<T2<Tn, so that φ2<φn is given. Therefore, the positions at which the dropped chemical solution contacts the substrate 3 are positions apart from the dropping position 87 in the order of L1, L2, and Ln.

When the above embodiment is used and the chemical solution is dropped on the rotating substrate 3, the positions on the substrate 3 at which the chemical solution contacts the substrate 3 are different from each other because the times for which the chemical solution is dropped are different in the cleaning steps, respectively. A small electrical discharge generated when the chemical solution contacts the substrate 3 will not be concentrated on one of the semiconductor devices formed on the semiconductor device region 4, thus improving the yield of the semiconductor devices. In addition, a special mechanism or modification of a sheet-type cleaning apparatus which performs the cleaning steps need not be implemented, thereby preventing the apparatus from a large scale. Note that although the dropping position 87 in FIGS. 8A and 8C is fixed regardless of the order of cleaning steps, different dropping positions 87 may be set in cleaning steps, respectively, thus obtaining a further effect.

### Seventh Embodiment

The seventh embodiment of the present invention will be described below. This embodiment is applied to cleaning steps to be performed in the manufacturing process of semiconductor devices according to the first to fourth embodiments. The processes in the cleaning steps are embodied. The arrangement of a sheet-type cleaning apparatus for performing cleaning steps is the same as in FIGS. 4A and 4B.

FIG. 8D shows the interior of a sheet-type cleaning apparatus for explaining a cleaning method according to this embodiment. FIG. 8D shows a chamber 11 in the sheet-type cleaning apparatus as in FIG. 5A from the upper surface. A substrate 3 is supported by chuck pins 22. FIG. 8D is different from FIG. 5A except that the substrate 3 is not rotated but kept stationary. In the first cleaning step of this embodiment, a dropping port 24 is aligned at a first dropping position 83 located in the upper portion of a semiconductor device region 4 on the substrate 3 by turning of a chemical solution nozzle. In the cleaning step of this embodiment, dropping of the chemical solution starts while the substrate 3 is kept stationary. The chemical solution is dropped for a predetermined period of time, and then substrate 3 starts rotating in a planar direction indicated by an arrow. A time from the start of dropping of the chemical solution to the start of rotation of the substrate 3 may be a short time. The time is set within the range of, for example 0.1 sec to 1 sec. The chemical solution is dropped for a desired period of time even after the start of rotation of the substrate 3, and then dropping is stopped. Dropping of pure water, drying by the rotation of the substrate 3, and unloading of the substrate 3, which will be performed subsequently, are the same as in the method described in the first embodiment, and a description thereof will be omitted. The first cleaning step has been completed. As shown in FIG. 3, after the end of a first cleaning step 301, the process reaches a second cleaning step 321 when the substrate 3 has undergone steps such as forming a film and dry etching in other apparatuses.

The second or subsequent cleaning step is performed in the same manner as in the first cleaning step except that the position of the dropping port 24 is aligned with an nth dropping position 85. The nth dropping position 85 is set at a position different from the first dropping position 83. In addition, the nth dropping position 85 is set as a position different from the dropping positions (not shown) in the second to (n−1)th cleaning steps.

In the cleaning steps according to the feature of this embodiment, the substrate 3 is kept stationary when the chemical solution is dropped on the substrate 3. After dropping of the chemical solution is started from the dropping port 24, the substrate 3 is rotated. The dropping port 24 is located on the semiconductor device region 4 on the surface of the substrate 3, and different dropping start positions are set in the cleaning steps, respectively.

In this embodiment, positions on the substrate 3 at which the chemical solution contacts the substrate 3 can be reliably made different from each other when the chemical solution is dropped on the substrate 3. A small electrical discharge generated when the chemical solution contacts the substrate 3 will not be concentrated on one of the semiconductor devices formed on the semiconductor device region 4, thus improving the yield of the semiconductor devices. In addition, a special mechanism or modification of a sheet-type cleaning apparatus which performs the cleaning steps need not be implemented, thereby preventing the apparatus from a large scale.

### Eighth Embodiment

The above embodiments have described the plurality of processing methods for the cleaning steps performed in the manufacturing processes of semiconductor devices. The eighth embodiment will describe a cleaning processing system which manages the cleaning processing according to the present invention.

FIG. 9A is a block diagram showing the schematic arrangement of a cleaning processing system according to this embodiment. A cleaning processing system 900 in FIG. 9A is arranged such that a sheet-type cleaning apparatus 901 and a controller 902 are connected to each other via a local area network (LAN) 903. The sheet-type cleaning apparatus 901 has an arrangement shown in FIGS. 4A and 4B and executes cleaning processing described with reference to the first to seventh embodiments under the control of the controller 902. The controller 902 manages cleaning processing executed by the sheet-type cleaning apparatus 901 for each substrate 3.

The controller 902 is formed from, for example, a personal computer. The controller 902 is connected to the sheet-type cleaning apparatus 901 via the LAN 903 in FIGS. 9A and 9B but may be incorporated in the sheet-type cleaning apparatus 901. The controller 902 may control the operation of the apparatus for performing the respective manufacturing steps in FIG. 3 in addition to the management of cleaning processing in the sheet-type cleaning apparatus 901.

FIG. 9B is a view showing an example of the hardware arrangement of the controller. In FIG. 9B, a CPU 911 executes an OS and application programs stored in an HD (Hard Disk) 913 and controls to temporarily store information and files required for execution of the programs in a RAM 912. The CPU 911 controls cleaning processing in the sheet-type cleaning apparatus 901 according to this embodiment. The RAM 912 functions as the main memory and work area of the CPU 911. The HD 913 stores application programs, driver programs, an OS, control programs, and processing programs for executing the control of cleaning processing according to this embodiment.

A display 914 is a display unit for displaying commands input from an operation unit 919, externally obtained information, and the like. An interface (to be referred to as an I/F hereinafter) 915 is a communication interface for connecting an external apparatus and a network. A ROM 916 stores programs such as a basic I/O program. An external storage drive 917 can load programs stored in a medium 918 into the computer system. The medium 918 serving as a storage medium stores a predetermined program and related data. The operation unit 919 is a user interface which allows an operator of this apparatus to input instructions and is made from a keyboard and a mouse. A system bus 920 controls the flow of data in the apparatus.

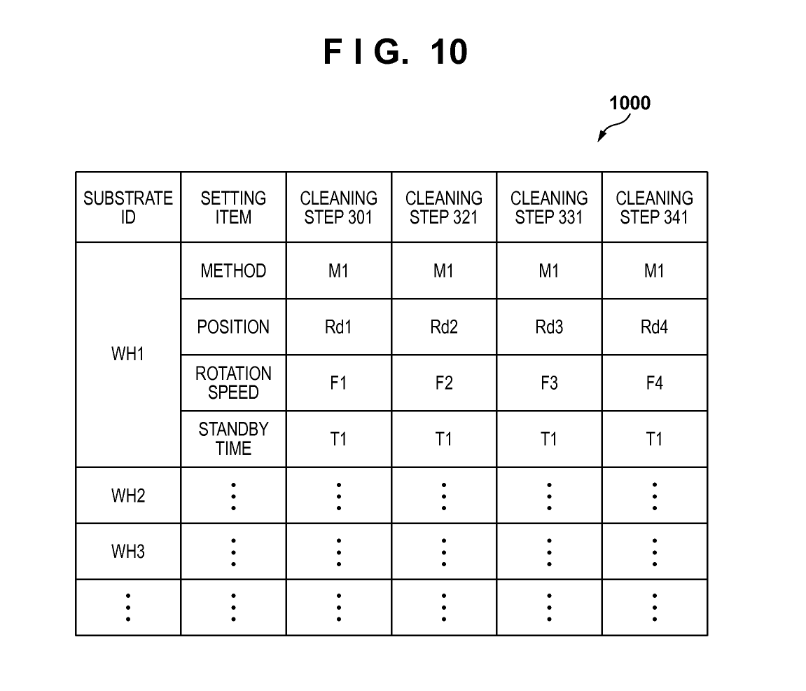

FIG. 10 is a view showing an example of the data structure of a management table used when the controller 902 manages the cleaning processing in the sheet-type cleaning apparatus 901. A table 1000 manages setting items serving as control variables in the respective cleaning steps for each substrate ID for uniquely managing a substrate as a processing target. More specifically, setting values representing cleaning processing methods, the chemical solution dropping start positions, the rotation speeds of the substrate 3, and standby time from the start of rotation of the substrate 3 to the start of dropping of the chemical solution are registered for cleaning steps 301, 321, 331, and 341 for each substrate. The setting values are set in advance before the start of the manufacturing process of semiconductor devices. However, some or all setting values may be newly set in the processing process or may be changed. The setting items in the table 1000 are merely examples. Any other setting items may be added. The controller 902 notifies the sheet-type cleaning apparatus 901 of the setting values when the corresponding cleaning step is started.

The respective setting items will be described below in detail. “Method” indicates each processing described from the first embodiment to the seventh embodiment. The respective processing methods from the first embodiment to the seventh embodiment are expressed by the setting values, for example, from M1 to M7. One of the values from M1 to M7 is registered in the table 1000. Note that the same method is employed for the plurality of cleaning steps for a single substrate in FIG. 10. However, the same method need not be employed for all the plurality of cleaning steps. Next, “positions” indicate the positions of a dropping port 24 when dropping of the chemical solution is started. The “positions” are set by the values of rotation angles Rd from the standby position 80 of the chemical solution nozzle 23. “Rotation speeds” indicate that values representing the rotation speeds [rpm] of the substrate 3 are set. The setting value may take a value falling within the range of 30 rpm to 1,000 rpm. “Standby time” indicates a value falling within the range of 0.5 sec to 10 sec in which the rotation speed of the substrate 3 reaches a sufficiently stable rotation speed.

The setting conditions of the respective setting items change depending on a method to be selected. For example, for the methods M1 to M3 according to the first to third embodiments, the rotation speed and the standby time are kept unchanged in the plurality of cleaning steps, but different positions are used in the cleaning steps, respectively. For the method M4 according to the fourth embodiment, different radial distances from the substrate center are set in the cleaning steps, respectively. However, the rotation speeds and the standby times may be the same or made different in the plurality of cleaning steps. For the method M5 according to the fifth embodiment, the positions and the standby times are the same in the plurality of cleaning steps, but different rotation speeds are set in the cleaning steps, respectively. For the method M6 according to the sixth embodiment, the positions and rotation speeds are the same in the plurality of cleaning steps, but different standby times are set in the cleaning steps, respectively. For the seventh embodiment, the positions are made different in the plurality of cleaning steps, respectively. However, the standby time is set to zero or a predetermined value indicating the start of dropping prior to the start of rotation. The rotation speed is set to an arbitrary value.

As described above, in the cleaning processing system according to this embodiment, when the chemical solution is dropped on the substrate 3, the positions on the substrate where the chemical solution contacts the substrate can be made different. A small electrical discharge generated when the chemical solution contacts the substrate 3 will not be concentrated on one of the semiconductor devices formed on the semiconductor device region 4, thus improving the yield of the semiconductor devices.

In the above embodiments, the semiconductor device region 4 is a region in which effective semiconductor devices are formed, but may be a portion in which ineffective semiconductor devices are formed. In addition, the above embodiments may be appropriately modified and combined.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-092000, filed Apr. 25, 2014, which is hereby incorporated by reference herein in its entirety.

What is claimed is:

1. A method of manufacturing a semiconductor device by performing a plurality of substrate cleaning steps including a process for supplying a chemical solution on a substrate transported into a cleaning apparatus, a process for rotating the substrate, and a process for unloading the substrate from the cleaning apparatus,
wherein in the plurality of cleaning steps, a dropping start position of the chemical solution on the substrate is set in a region on the substrate where the semiconductor device has been formed, and the dropping start position is changed at least once.

2. The method according to claim 1, wherein in the cleaning steps, after dropping of the chemical solution on the substrate is started, the dropping position is shifted toward a central direction of the substrate while the dropping is continued.

3. The method according to claim 1, wherein in the plurality of cleaning steps, the dropping start position is set within a region near a center of the substrate.

4. The method according to claim 3, wherein the region near the center is a region within a circle which is ½ to ¼ a radius of the substrate.

5. The method according to claim 1, wherein in the plurality of cleaning steps, the dropping start positions are made different in a radial direction of the substrate.

6. The method according to claim 1, wherein a speed for rotating the substrate and a time from a start of rotation of the substrate to dropping of the chemical solution are kept unchanged in the plurality of cleaning steps.

7. The method according to claim 1, wherein in the plurality of cleaning steps, the substrate is rotated after dropping of the chemical solution on the substrate is started.

8. The method according to claim 1, wherein in the plurality of cleaning steps, a time from a start of rotation of the substrate to dropping of the chemical solution is kept unchanged, and rotation speeds of the substrate at the time of the dropping are made different.

9. The method according to claim 1, wherein in the plurality of cleaning steps, a speed for rotating the substrate is kept unchanged, and times from a start of rotation of the substrate to dropping of the chemical solution are made different.

10. The method according to claim 1, wherein in the plurality of cleaning steps, a position at the time of starting rotation of the substrate is kept unchanged in the cleaning apparatus.

11. The method according to claim 1, wherein the dropping start positions are made different in cleaning steps performed after forming a transistor on the substrate out of the plurality of cleaning steps.

12. A cleaning processing system including:
a chamber;
a base which supports and rotates a substrate in said chamber;
a cleaning portion configured to drop a chemical solution on the substrate on said base and clean the substrate; and
a controller configured to control cleaning by said cleaning portion,
the cleaning processing system performing a plurality of cleaning steps including a process for supplying the chemical solution onto the substrate transported into said chamber and supported on said base, a process for rotating the substrate, and a process for unloading the substrate from said cleaning portion,
wherein in the plurality of cleaning steps, said controller controls said cleaning portion such that a dropping start position of the chemical solution on the substrate is set in a region on the substrate where a semiconductor has been formed, and the dropping start position is changed at least once.
